(19) United States
(12) Patent Application Publication
(10) Pub. No.: US 2017/0176520 A1
(43) Pub. Date: Jun. 22, 2017

(54) TUNABLE WAVELENGTH ELECTRO-OPTICAL ANALYZER

(71) Applicant: QUALCOMM Incorporated, San Diego, CA (US)

(72) Inventors: Ulrike Kindereit, Berlin (DE); Victoria Bruce, Fredericksburg, TX (US)

(21) Appl. No.: 15/269,751

(22) Filed: Sep. 19, 2016

Related U.S. Application Data
(60) Provisional application No. 62/268,928, filed on Dec. 17, 2015.

(51) Int. Cl. G01R 31/311; H01S 3/13

(52) U.S. Cl. CPC G01R 31/311; H01S 3/1305

(57) ABSTRACT

An electro-optical analyzing system is provided with a wavelength tunable laser so that a DUT may be laser illuminated at different wavelengths. The signal qualities are determined corresponding to a reflection from the DUT of illumination of the laser at multiple wavelengths. The signal quality for each wavelength can be compared to a threshold signal quality over a range of wavelengths or compared to each other to identify a wavelength that increases resolution and decreases destructive interference and cross-talk,

### CROSS-REFERENCE TO RELATED APPLICATIONS

This application claims the benefit of U.S. Provisional Application No. 62/268,928, filed Dec. 17, 2015.

### TECHNICAL FIELD

This application relates to electro-optical analyzer for integrated circuits (ICs), and more particularly to tunable wavelength electro-optical analyzer.

### BACKGROUND

To determine the behavior of signals such as carried on traces in a circuit board, a technician may probe the traces directly with tools such as oscilloscopes. But the transistors in a modem integrated circuit (IC) are not amenable to such direct sampling due to the high integration and smaller node sizes of components in the IC. To enable the equivalent of a direct probe for testing and debugging such otherwise inaccessible devices, electro-optical analyzer systems such as a laser voltage probe system have been developed. These techniques take advantage of the relative transparency of semiconductor substrates such as silicon to certain wavelengths of light. For example, electro-optical probing of voltage waveforms in typical Complementary Metal Oxide Semiconductor (CMOS) circuits is possible because a response from an active region in the circuit is generally readily detectable through the silicon. A depletion region at the p-n junction of a CMOS transistor has a strong electric field responsible for changes in the refractive index and in the light absorption coefficient of silicon at the junction. When examined through the bulk silicon, the relatively uncomplicated structure of the CMOS junction regions and the strong electric field exhibited by the depletion region both support electro-optical probing whereby a response from the circuits can be detected.

To increase this transparency, the device under test (DUT) typically undergoes a backside thinning of the substrate. The DUT then receives some stimulus such as a signal test vector while the laser voltage probing (LVP) system illuminates the thinned backside surface of the DUT's substrate at the intended location, e.g., a region of a target transistor. Based upon landmarks on the DUT, the laser voltage probing system may be assured that it is illuminating a desired portion of the DUT's die.

In addition to laser voltage probing, a related technique known as dynamic laser stimulation (DLS) also involves the illumination of the DUT by a laser while the DUT receives an input signal test vector or other stimulus. In response to the input signal test vector, the DUT provides an output vector (e.g, a digital signal such as a digital word or clock). This output vector is either correct or it is not. If the output vector is proper, the DUT is functional despite the laser stimulus it receives during the DLS procedure. In contrast to LVP, DLS determines the presence of soft faults such as a susceptibility to heat. For example, an infrared laser in a DLS system may heat the DUT such that the output vector indicates a failure. Alternatively, a visible light (or ultraviolet) laser may stimulate electron-hole pairs in the DUT that cause a failure in the output vector.

Whereas a DLS procedure examines the presence of soft failures in the DUT, a LVP test identifies hard failures. For example, the input test vector may be a clocking signal having some RF frequency. If the transistor being illuminated in the DUT is operating correctly, it will cycle according to the RF frequency of the input test vector. The reflected laser light from the DUT will thus have a corresponding RF modulation if the illuminated transistor is functioning properly. But both DLS and LVP suffer from non-idealities in practice. For example, interfaces between different materials in the DUT may make it difficult to obtain an optical response, for example, due to changes in refractive index that occur at each interface. These changes in refractive index result in undesired reflected light. This undesired reflected light may interfere with the portion of the reflected light that is useful, for example, for analyzing the circuit. As the process nodes for the DUTs becomes ever more advanced, laser voltage probing and dynamic laser stimulation both suffer from signal strength reduction, worsened resolution, increased cross-talk, and destructive interference. These deleterious effects lead to unreliable and unrepeatable measurements as well as long debug times.

Accordingly, there is a need in the art for improved electro-optical analyzing systems.

### SUMMARY

To provide reliable measurements, a wavelength-tunable electro-optical analyzing system is provided that provides improved testing resolution. In particular, the system includes one or more wavelength-tunable lasers that may be manually or automatically tuned during a laser voltage probing analysis or a dynamic laser stimulation of an integrated circuit device under test (DUT). The bandwidth or tuning range over which the wavelengths are tuned may include the conventional wavelengths of 1064 nm and 1340 (or 1319) nm and may span a wavelength range including all of infrared (IR) to ultraviolet (UV) wavelengths. Alternatively, the tuning range may include just parts of these bands.

By sweeping through this tuning range, an electro-optical analysis may find the wavelength that provides the greatest response for a particular circuit being analyzed such that the destructive interference that vexes conventional fixed-wavelength analyses is eliminated or reduced and resolution is increased.

### BRIEF DESCRIPTION OF THE DRAWINGS

FIG. 1A illustrates an example laser voltage probing system in accordance with an aspect of the disclosure.

FIG. 1B illustrates an example dynamic laser stimulation system in accordance with an aspect of the disclosure.

FIG. 2 is a flow chart showing an example method of operation for the system of FIG. 1A.

FIG. 3 illustrates another example laser voltage probing system in accordance with an aspect of the disclosure.

FIG. 4 is a flow chart showing an example method of operation for the system of FIG. 3.

FIG. 5 is a flow chart showing another example method of operation for the system of FIG. 3.

Embodiments of the disclosure and their advantages are best understood by referring to the detailed description that follows. It should be appreciated that like reference numerals are used to identify like elements illustrated in one or more of the figures.

### DETAILED DESCRIPTION

Tunable electro-optical analyzing systems are provided to provide improved resolution and reliability. There are two main embodiments for the tunable electro-optical analyzing systems disclosed herein. A first embodiment of the tunable electro-optical analyzing system is a laser voltage probe (LVP) system, which is a laser-based voltage and timing waveform acquisition system used to perform failure analysis on integrated circuits (ICs). The device under test (DUT) is de-encapsulated in order to expose the backside of the die. The silicon substrate is then thinned, e.g., using a backside mechanical thinning tool. The thinned DUT is then mounted on a movable stage and connected to an electrical stimulus source. Signal measurements are performed through the back side of the DUT after substrate thinning has been performed. The DUT must be electrically stimulated using a repeating test pattern, with a trigger pulse provided to the LVP system as reference.

The LVP system detects an RF modulation of reflected laser light from the device diffusion regions. Device imaging is accomplished through the use of a laser scanning microscope. The LVP uses an infrared (IR) or visible light laser to perform device imaging and waveform acquisition. On an electrically active device, the LVP system monitors the changes in the phase of an electromagnetic field surrounding a signal being applied to a device junction such as a transistor p-n junction (the junction between p-doped semiconductor and n-doped semiconductor).

The LVP system obtains voltage waveform and timing information by monitoring the interaction of laser light with the changes in the electric field across the p-n junction in the DUT. As the laser light propagates to the p-n junction, a certain amount of that light is reflected back. The amount of reflected laser light from the p-n junction is sampled at various points in time. The changing electromagnetic field at the p-n junction affects the amount of laser light that is reflected back. By detecting the variations in reflected laser light versus time (the RF modulation of the reflected laser responsive to the input signal exciting the transistor including the p-n junction), it is possible to construct a timing waveform of the signal at the junction. As the test pattern continues to loop, additional measurements are acquired and averaged into the previous measurements. Over a period of time, this averaging of measurements produces a more refined waveform. The end result is a waveform that is representative of the electrical signal present at the p-n junction.

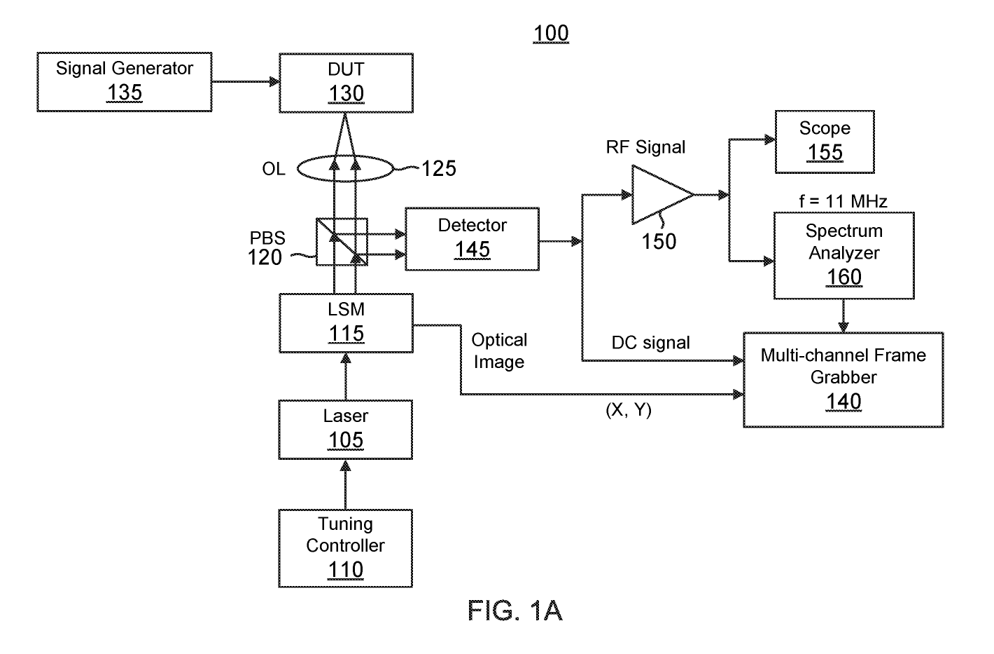

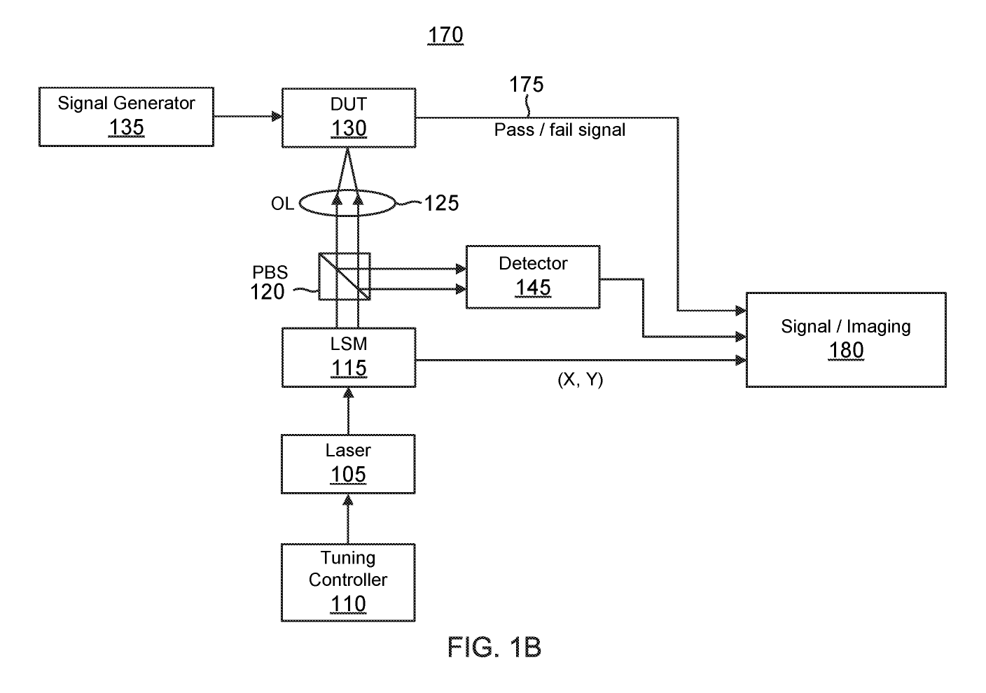

Turning now to the drawings, an exemplary LVP system 100 includes a wavelength-tunable laser 105 as shown in FIG. 1A. One type of wavelength tunable laser is as a titanium-sapphire laser that produces laser illumination having a wavelength that can be tuned. In the device, a set of disks of titanium-sapphire are placed in a holder that allows the simultaneous rotation of the plates in their own respective planes. By varying the angle, the laser emission can be spectrally tuned over a range of wavelengths. The tuning range or bandwidth for laser 105 may vary in alternative implementations, but may range from IR to UV and include the typically-used wavelengths of 1064 nm and 1340/1319 nm.

A tuning controller 110 controls the laser illumination wavelength from laser 105. Tuning controller 110 may be manually or automatically controlled as will be discussed further herein. The laser illumination from laser 105 passes through a laser scanning module 115 and a polarizing beam splitter 120 before being focused in an objective lens 125 onto the thinned backside surface of a DUT die 130. During an analysis by LVP system 100, DUT 130 receives a signal test vector from a signal generator 135 such as a pulse generator.

Laser scanning module 115 produces an optical image (X,Y) that is sampled in a multi-channel frame grabber 140. However, it will be appreciated that other signal detection schemes in lieu of frame grabbing may be implemented. By identifying circuit landmarks in the resulting optical image, a technician using system 100 can be assured that the desired target circuitry, e.g., a depletion region in a transistor, within DUT 130 is being illuminated by laser 105.

The illuminated transistor will have varying optical parameters in response to the excitation from signal generator 135. These varying optical parameters modulate the reflected laser light from DUT 130 that is received by polarizing beam splitter 120 and directed to a detector 145. For example, if signal generator 135 produces an 11 MHz excitation of DUT 130 and DUT 130 is operating normally in response to this excitation, a detected signal from detector 145 will have an 11 MHz RF component. An RF amplifier 150 amplifies the RF signal to drive an oscilloscope 155 and/or a spectrum analyzer 160. The DC component of the detected signal is used to generate the optical image of DUT 130. It will be appreciated that spectrum analyzer 160 may be replaced by alternative analyzers such as an off-board data analyzer in alternative embodiments.

During a fault analysis of DUT 130, a technician may tune laser 105 through tuning controller 110 to use a first wavelength (λ_1), e.g., 1064 nm, and observe the resulting signal quality at spectrum analyzer 160 and/or oscilloscope 155. If the signal quality is poor such as from destructive interference, the technician may then adjust tuning controller 110 so that laser 105 adjusts to another suitable frequency (λ_2), e.g., 1340 nm. The tuning of laser 105 is quite advantageous in that destructive interference is a function of the internal device layer and substrate thickness (among other factors) in DUT 130 and the wavelength selected for tunable laser 105. To counteract this destructive interference, the wavelength of laser 105 may be selected accordingly. Other deleterious effects such as cross-talk may be reduced in the same fashion through appropriate selection of the laser wavelength.

The benefits of tuning laser 105 may be enjoyed by a DLS system 170 as shown in FIG. 1B. DLS system 170 includes a tuning controller 110, a laser scanning module 115, a PBS 120, a detector 145, an objective lens 125, and a DUT 130 as discussed with regard to LVP system 100. However, in DLS system 170, DUT produces a pass/fail signal 175 responsive to a digital input vector from signal generator 135. A signal processing and imaging module 180 receives the output of detector 145, LSM 115, and pass/fail signal 175. For example, signal processing and imaging module 180 may include a spectrum analyzer 160 and frame grabber 140 as discussed with regard to LVP system 100. However, the signal quality for DLS system 170 may be determined through an analysis of pass/fail signal 175 such as through a logic analyzer or through a suitable automatic test equipment (ATE). It will be appreciated that pass/fail signal 175 may be generated by the ATE in some embodiments. A quality decision based upon, for example, the output of detector 145 may then be used either manually or automatically to tune laser 105 through tuning controller 110.

In contrast to LVP system 100, DLS system 170 detects the presence of soft failures that result when the laser stimulation pushes pass/fail signal 175 from a passing state to a failing state. These types of failures are said to be “soft” if they only occur under certain voltage, temperature, or frequency ranges. Typically these are toward the edge or corner of an operational window or box as defined in the product specification. These failures can also occur under certain functional conditions, for instance a type of operation that places additional stress on an IC, like a graphics-intensive routine in a microprocessor. A DLS analysis is becoming more important because an increasing fraction of today's advanced ICs fails “soft.” Problems due to process variations lead to these failures. Shrinking feature sizes lead to more variability, as the tolerance cannot be scaled at the same rate as the feature size. The uses of Resolution Enhancement Techniques (RETS) like optical proximity correction, phase shift masks, and double patterning lead to variations in lithography that are difficult to accurately model during the design process. Variations in chemical mechanical planarization due to surface density effects and other issues also contribute to this problem. DLS allows a circuit manufacture to identify these soft failures to improve product quality.

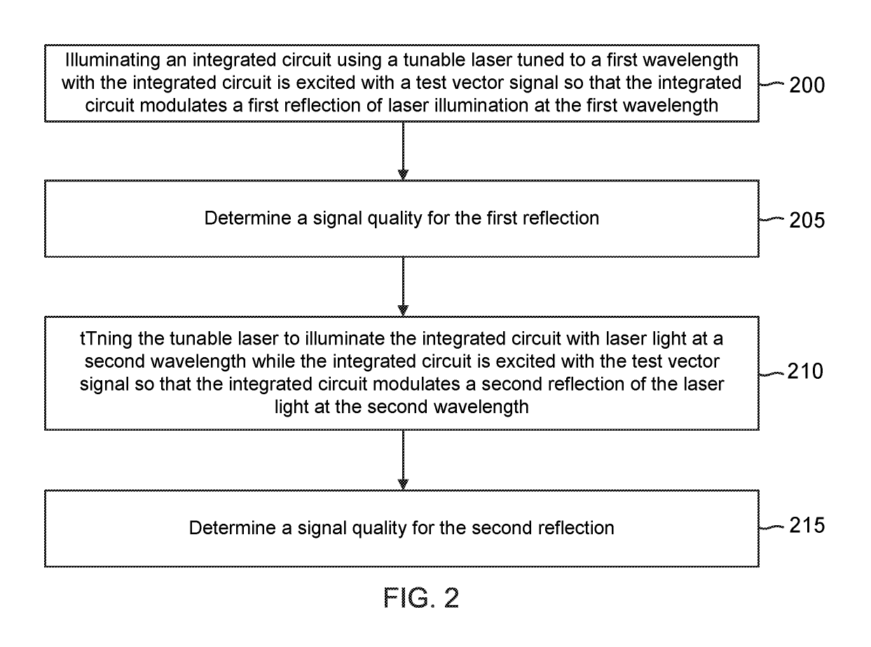

But LVP system 100 detects the presence of hard failures that exist regardless of whether DUT 130 is stimulated by laser light. Despite these differences, the methods of operation for LVP system 100 and DLS system 170 are analogous. For example, a method of operation for system 100 will now be discussed with regard to FIG. 2. The method includes an act 200 of illuminating a target on an integrated circuit using a tunable laser tuned to a first wavelength (λ_1) while the integrated circuit is excited with a test vector signal so that the integrated circuit modulates a first reflection of laser illumination at the first wavelength. In addition, the method includes an act 205 of determining a signal quality for the first reflection. For DLS system 170, act 200 would instead take place while the integrated circuit processes an input test vector into a pass/fail signal. Should the signal quality be poor, the method may continue with an act 210 of tuning the tunable laser to illuminate the integrated circuit with laser light at a second wavelength (λ_2) while the integrated circuit is excited with the test vector signal so that the integrated circuit modulates a second reflection of the laser light at the second wavelength followed by an act 215 of determining a signal quality for the second reflection. It will be appreciated that act 210 in DLS system 170 would instead take place while the integrated circuit processes an input test vector into a pass/fail signal. The wavelength that exhibits the best quality may then be selected for use in the LVP operation in act 220. In this fashion, the laser may be tuned so as to improve the resolution of the resulting laser voltage probing (or dynamic laser stimulation) analysis.

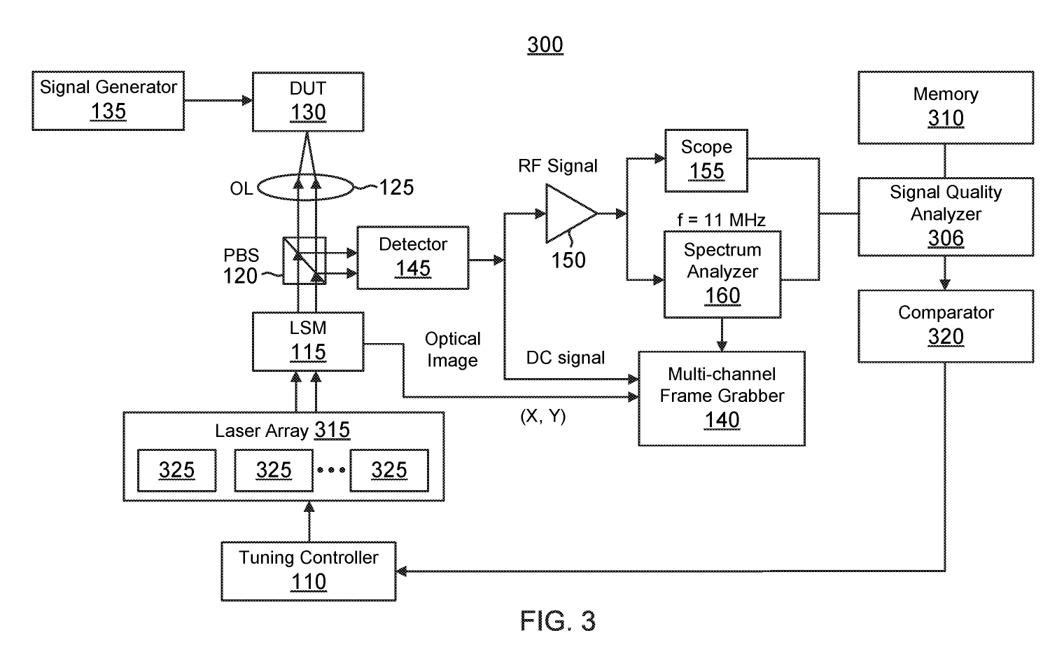

As described above, the control of the tuning controller 110 to tune and select the wavelength to be used to perform the LVP operation may be performed automatically by either LVP system 100 or DLS system 170. For example, FIG. 3 shows another exemplary LVP system 300 that provides automatic tuning to the wavelength determined to be best for a particular LVP analysis. In LVP system 300, tuning controller 110, LSM 115, PBS 120, objective lens 125, signal generator 135, DUT 130 detector 145, RF amplifier 150, frame grabber 140, spectrum analyzer 160, and oscilloscope 155 function as discussed with regard to LVP system 100. A signal quality analyzer 306 receives information from oscilloscope 155 and/or spectrum analyzer 160. Signal quality analyzer 306 uses this information to determine a quality for the RF signal from RF amplifier 150 (for example, the signal-to-noise ratio for the RF signal) and may store that information in a memory 310. A comparator 320 functions to compare the signal quality (such as retrieved from memory 310) for an analysis at one wavelength to an analysis at a different wavelength to determine which wavelength is preferable with regard to tuning through tuning controller 110.

In LVP system 300, laser 105 may be replaced by a wavelength tunable laser array 315 which includes two or more lasers 325, each dedicated to a single wavelength, e.g., two lasers producing typically used wavelengths 1640 nm or 1340/1319 nm, respectively. Alternatively, for greater resolution, each of the lasers in the laser array may be individually tunable over a different range of wavelengths of interest. Tuning controller 110 controls which laser in the laser array (and also a specific wavelength if the laser is tunable) is illuminating DUT 130 depending upon what wavelength is desired.

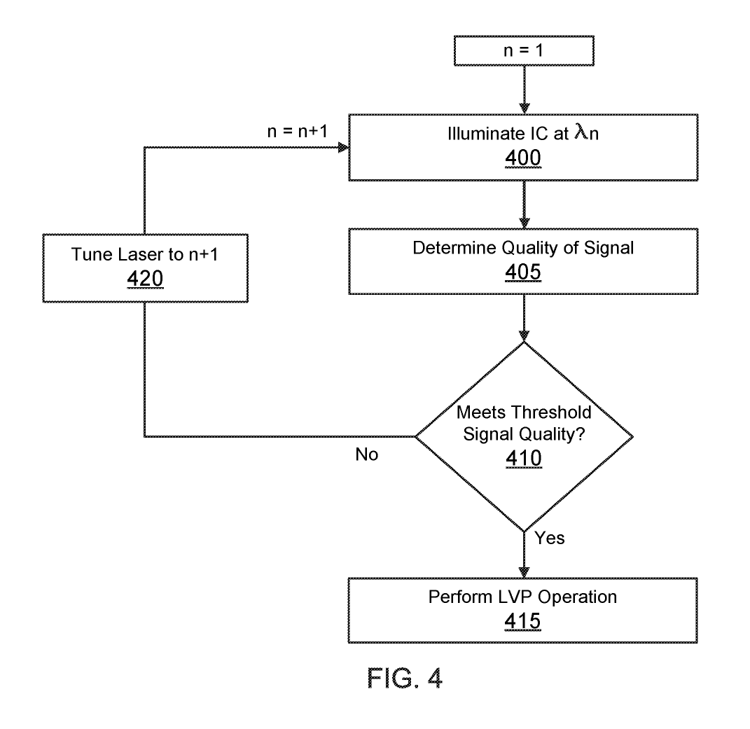

FIG. 4 shows a method of operation for system 300. The method includes an act 400 of illuminating a target on an integrated circuit using a tunable laser tuned to a first wavelength (λ_n) where n=1 while the integrated circuit is excited with a test vector signal so that the integrated circuit modulates a first reflection of laser illumination at the first wavelength. In an act 405, the signal quality analyzer determines the quality of the signal and next determines whether it meets a minimum threshold signal quality in act 410. If so, the method continues with an act 415 of performing the LVP at wavelength If not, the method continues with an act 420 of tuning the tunable laser to a next wavelength (λ_n+1), in this case, and then returning to act 400 by illuminating the integrated circuit with laser light at the next wavelength (λ_2) while the integrated circuit is excited with the test vector signal so that the integrated circuit modulates a second reflection of the laser light at the λ_2 wavelength. If it is determined that the signal quality meets or exceeds the threshold signal quality in act 410, the LVP process is performed at λ_2. If not, the process is repeated until a wavelength is found that meets the minimum signal quality threshold criteria. The initial wavelength λ_1 and sequence of subsequent wavelengths to be tested may be pre-selected, or may be based on increasing or decreasing the previously tested wavelength by some interval.

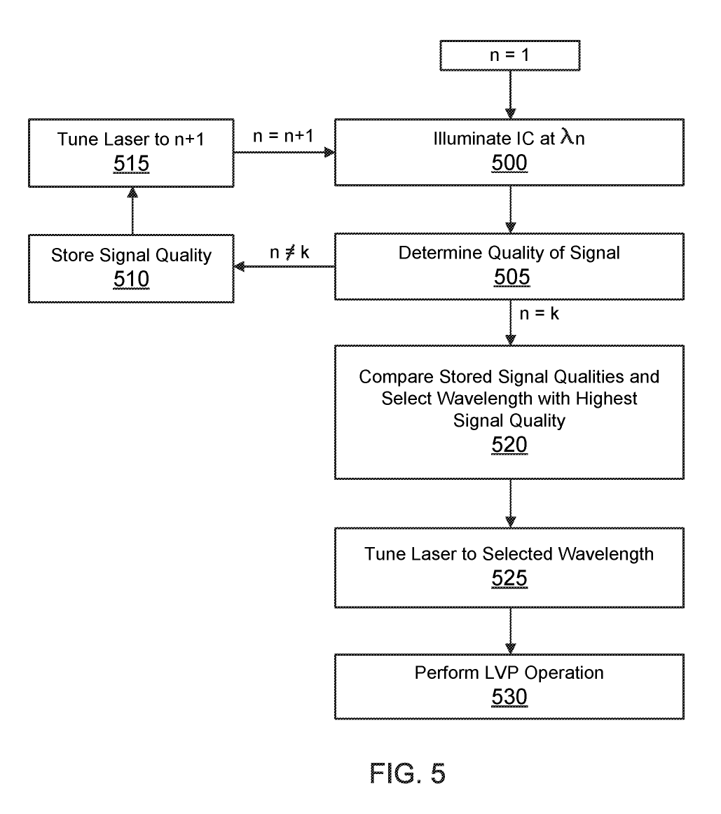

FIG. 5 shows an alternative method of operation for system 300 in which a range of wavelengths are tested before a final wavelength is selected. The method includes an act 500 of illuminating a target on an integrated circuit using a tunable laser tuned to a first wavelength (λ_n) where n=1 while the integrated circuit is excited with a test vector signal so that the integrated circuit modulates a first reflection of laser illumination at the first wavelength. In an act 505, the signal quality analyzer determines the quality of the signal and then stores the signal quality information for that wavelength in the memory 310 in act 510. The method continues with an act 515 of tuning the tunable laser to a next wavelength (λ_n+1), and returns to act 500 by illuminating the integrated circuit with laser light at the next wavelength while the integrated circuit is excited with the test vector signal so that the integrated circuit modulates the next reflection of the laser light at the next wavelength. This process continues until the signal quality of a final wavelength (λ_k) in the range of wavelengths is determined and stored. The method continues with an act 520 in which the signal quality analyzer uses a comparator 320 to compare the stored signal qualities for the tested wavelengths and selects the wavelength with the highest signal quality. Then in act 425, the tuning controller 110 tunes the wavelength tunable laser to the selected wavelength, e.g., by selected the laser in the laser array 315 that produced the wavelength, and LVP is performed in act 530.

As those of some skill in this art will by now appreciate and depending on the particular application at hand, many modifications, substitutions and variations can be made in and to the materials, apparatus, configurations and methods of use of the devices of the present disclosure without departing from the scope thereof. In light of this, the scope of the present disclosure should not be limited to that of the particular embodiments illustrated and described herein, as they are merely by way of some examples thereof, but rather, should be fully commensurate with that of the claims appended hereafter and their functional equivalents.

We claim:

1. An electro-optical analysis system, comprising:
a wavelength tunable laser configured to respond to a tuning control signal to generate laser light having a wavelength adjusted responsive to the tuning control signal;
a signal generator configured to excite an integrated circuit with a test vector signal; and
a detector configured to detect laser light from the wavelength tunable laser reflected by the integrated circuit while the integrated circuit is excited by the test vector signal.

2. The system of claim 1, further comprising:
a tuning controller configured to generate the tuning control signal.

3. The system of claim 2, further comprising:
a signal quality analyzer configured to generate a signal quality from the detected laser light corresponding to a wavelength generated by the wavelength tunable laser.

4. The system of claim 3, further comprising:
a comparator configured to:
compare a plurality of signal qualities received from the signal quality analyzer, each signal quality corresponding to a different wavelength;
select a wavelength corresponding to a highest signal quality; and
transmit information identifying said wavelength to the tuning controller.

5. The system of claim 4, wherein the comparator is further configured to compare the plurality of signal qualities against each other after receiving signal qualities corresponding to a predetermined range of wavelengths.

6. The system of claim 4, wherein the comparator is further configured to compare each of the plurality signal quality to a threshold signal quality.

7. The system of claim 1, wherein the wavelength tunable laser comprises at least two lasers, each laser dedicated to a corresponding wavelength range.

8. The system of claim 1, further comprising a spectrum analyzer configured to analyze an RF component of a detected signal from the detector.

9. A method, comprising:
illuminating an integrated circuit using a wavelength tunable laser tuned to a first wavelength while the integrated circuit is excited with a test vector signal so that the integrated circuit modulates a first reflection of laser illumination at the first wavelength;
determining a signal quality for the first reflection;
tuning the wavelength tunable laser to illuminate the integrated circuit with laser light at a second wavelength while the integrated circuit is excited with the test vector signal so that the integrated circuit modulates a second reflection of the laser light at the second wavelength; and
determining a signal quality for the second reflection.

10. The method of claim 9, further comprising:
comparing the signal qualities of the first reflect and the second reflection; and
selecting a wavelength corresponding to a higher signal quality.

11. The method of claim 10, further comprising:
tuning the wavelength tunable laser to the wavelength with the selected signal quality; and
performing an electro-optical analysis operation on the integrated circuit.

12. The method of claim 9, further comprising:
illuminating in a sequence the integrated circuit using the wavelength tunable laser tuned to each of a plurality of wavelengths while the integrated circuit is excited with the test vector signal so that the integrated circuit modulates a plurality of reflections of laser illumination at each of the plurality of wavelengths; and
determining a signal quality for each of the plurality of reflections.

13. The method of claim 12, further comprising:
comparing each of the signal qualities in sequence to a threshold signal quality; and
selecting a wavelength that meets or exceeds the threshold signal quality.

14. The method of claim 12, further comprising:
comparing each of the plurality of signal qualities to each other; and
selecting a wavelength with the highest signal quality.

15. An electro-optical analysis system, comprising:
a wavelength tunable laser configured to respond to a tuning control signal to generate laser light having a wavelength adjusted responsive to the tuning control signal;
means for exciting an integrated circuit with a test vector signal; and
means for detecting laser light from the wavelength tunable laser reflected by the integrated circuit while the integrated circuit is excited by the test vector signal.

16. The system of claim 15, further comprising:
means for generating the tuning control signal.

17. The system of claim 16, further comprising:
means for generating a signal quality from the detected laser light corresponding to a wavelength generated by the wavelength tunable laser.

18. The system of claim 16, further comprising a means for receiving a pass/fail signal from the integrated circuit.

19. The system of claim 18, wherein the system is a dynamic laser stimulation system.

20. The system of claim 15, wherein the test vector signal is an RF signal.
